(19) United States
(12) Patent Application Publication
(10) Pub. No.: US 2010/0207182 A1
(43) Pub. Date: Aug. 19, 2010

(54) Implementing Variable Threshold Voltage Transistors

(75) Inventor: Matthew James Paschal, Rochester, MN (US)

Correspondence Address: IBM CORPORATION;ROCHESTER IP LAW DEPT 917, 3605 HIGHWAY 52 N, ROCHESTER, MN, 55901-7829, US

(73) Assignee: INTERNATIONAL BUSINESS MACHINES CORPORATION, Armonk, NY (US)

(21) Appl. No.: 12/370,848

(22) Filed: Feb. 13, 2009

(51) Int. Cl. H01L 29/78; H01L 21/336; G06F 9/45

(52) U.S. Cl. 257/314; 257/369; 438/199; 716/5; 257/E29.255; 257/E21.409

(57) ABSTRACT

A circuit and method for implementing variable threshold voltage transistors in a complementary metal oxide semiconductor (CMOS) semiconductor chip, and a design structure on which the subject circuit resides are provided. Variable threshold voltage transistors are provided utilizing the NWELL and PWELL proximity effects of the CMOS semiconductor chip without any additional mask steps. A distance between an adjacent field effect transistor (FET) and an NWELL edge or PWELL edge is adjusted to selectively provide a needed threshold voltage for the FET.

### FIELD OF THE INVENTION

The present invention relates generally to the data processing field, and more particularly, relates to a circuit and method for implementing variable threshold voltage transistors, and a design structure on which the subject circuit resides.

### DESCRIPTION OF THE RELATED ART

Complementary metal oxide semiconductor (CMOS) silicon technologies typically contain various N-channel field effect transistors (NFETs) and P-channel field effect transistors (PFETs) with fixed nominal threshold voltages (Vt).

Electronic circuit designs typically use these fixed Vt transistors to realize a specified function. As a result, the circuit topology is often complex in order to overcome the fact that the CMOS technology has a fixed number of transistor types, all with fixed nominal threshold voltages.

Currently, adjusting threshold voltages of CMOS transistors can be accomplished by biasing the transistor wells to a voltage other than the voltage supply rail (Vdd) for NWELLs or a voltage other than ground potential (Gnd) for PWELLs. However, this method is very limited by the number of well bias voltages available, for example, due to the physical size of using multiple biasing circuits to tune the threshold voltages of multiple transistors. Additionally, NFETs in a P-type silicon substrate and PFETs in an N-type silicon substrate do not have wells that can be biased to an intermediate voltage between Vdd and Gnd.

A need exists for an effective mechanism for selectively adjusting threshold voltages of CMOS transistors as part of the design process.

### SUMMARY OF THE INVENTION

Principal aspects of the present invention are to provide a circuit and method for implementing variable threshold voltage transistors in a complementary metal oxide semiconductor (CMOS) semiconductor chip, and a design structure on which the subject circuit resides. Other important aspects of the present invention are to provide method, circuit and design structure substantially without negative effect and that overcome many of the disadvantages of prior art arrangements.

In brief, a circuit and method for implementing variable threshold voltage transistors in a complementary metal oxide semiconductor (CMOS) semiconductor chip, and a design structure on which the subject circuit resides are provided. Variable threshold voltage transistors are provided utilizing the NWELL and PWELL proximity effects of the CMOS semiconductor chip. A distance between an adjacent field effect transistor (FET) and an NWELL edge or PWELL edge is adjusted to selectively provide a needed threshold voltage for the FET.

In accordance with features of the invention, by adjusting the distance between an NWELL edge or a PWELL edge and an adjacent N-channel field effect transistor (NFET), the threshold voltage for the NFET transistor is changed.

In accordance with features of the invention, by adjusting the distance between an NWELL edge or a PWELL edge and an adjacent P-channel field effect transistor (PFET), the threshold voltage for the PFET transistor is changed.

In accordance with features of the invention, the adjacent NWELL or PWELL edge includes an inner edge of an NWELL Ring or PWELL Ring around the entire NFET or PFET.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1 and 2 are block diagram representations illustrating a computer system and operating system for implementing CMOS circuits having variable threshold voltage transistors in accordance with the preferred embodiment;

FIG. 3 is a schematic diagram representation of an example CMOS circuit having variable threshold voltage transistors in accordance with the preferred embodiment;

FIG. 4 is a flow chart illustrating exemplary steps for implementing CMOS circuits having variable threshold voltage transistors in accordance with the preferred embodiment;

FIGS. 5 and 6 illustrate a respective implantation process for NWELLs in accordance with the preferred embodiment;

FIG. 7 is a chart illustrating example NWELL proximity effects on an NFET in accordance with the preferred embodiment;

FIG. 8 illustrates an example CMOS circuit having a variable threshold voltage NFET selectively spaced from an NWELL in accordance with the preferred embodiment;

FIG. 9 illustrates an example CMOS circuit having a variable threshold voltage NFET selectively spaced from an NWELL Ring in accordance with the preferred embodiment;

FIG. 10 is a chart illustrating example NWELL proximity effects on an NFET inside an NWELL Ring in accordance with the preferred embodiment; and

FIG. 11 is a flow diagram of a design process used in semiconductor design, manufacturing, and/or test.

### DETAILED DESCRIPTION OF THE PREFERRED EMBODIMENTS

In accordance with features of the invention, a method and circuit are provided for implementing variable threshold voltage field effect transistors using NWELL and PWELL proximity effects. The NWELL proximity effects increase the Vt of PFETs and decrease the Vt of NFETs. The PWELL proximity effects increase the Vt of NFET transistors and decrease the Vt of PFET transistors. The amount of Vt shift depends on the proximity of the FET transistor to the NWELL and PWELL edges.

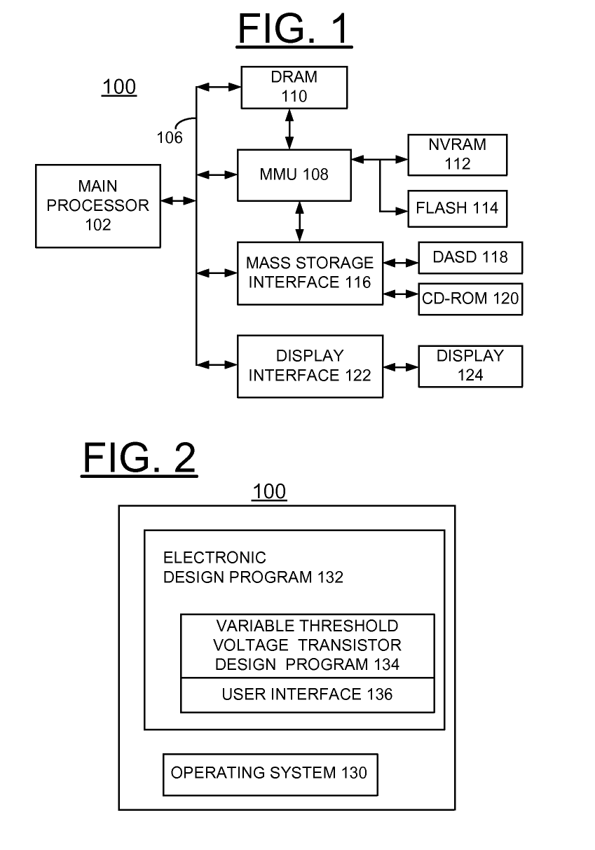

Having reference now to the drawings, in FIGS. 1 and 2 there is shown a computer system generally designated by the reference character 100 for implementing CMOS circuits having variable threshold voltage transistors in accordance with the preferred embodiment. Computer system 100 includes a main processor 102 or central processor unit (CPU) 102 coupled by a system bus 106 to a memory management unit (MMU) 108 and system memory including a dynamic random access memory (DRAM) 110, a nonvolatile random access memory (NVRAM) 112, and a flash memory 114. A mass storage interface 116 coupled to the system bus 106 and MMU 108 connects a direct access storage device (DASD) 118 and a CD-ROM drive 120 to the main processor 102. Computer system 100 includes a display interface 122 coupled to the system bus 106 and connected to a display 124.

Computer system 100 is shown in simplified form sufficient for understanding the present invention. The illustrated computer system 100 is not intended to imply architectural or functional limitations. The present invention can be used with various hardware implementations and systems and various other internal hardware devices, for example, multiple main processors.

As shown in FIG. 2, computer system 100 includes an operating system 130, an electronic package design program 132, a variable threshold voltage transistor design program 134 of the preferred embodiment, and a user interface 136.

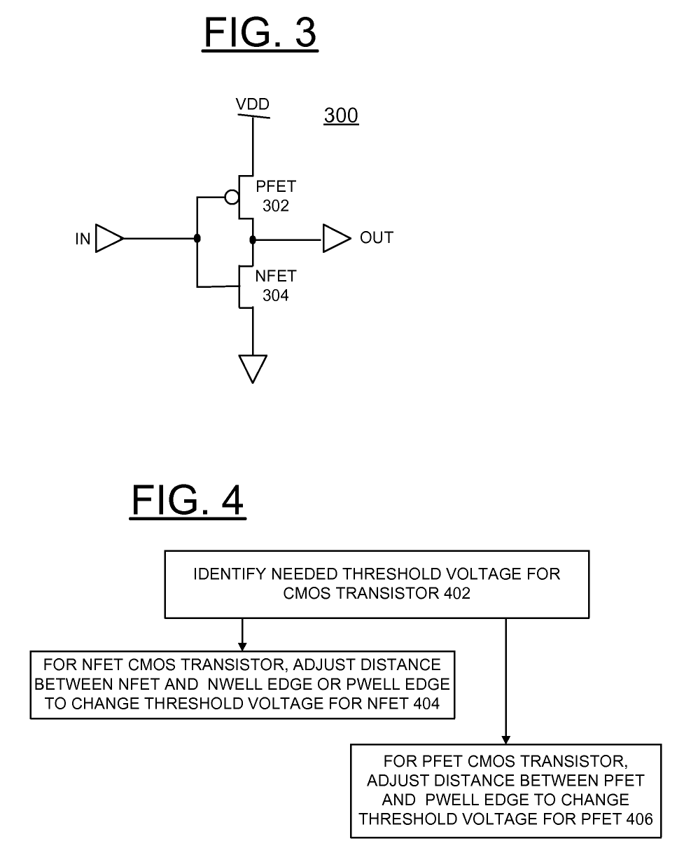

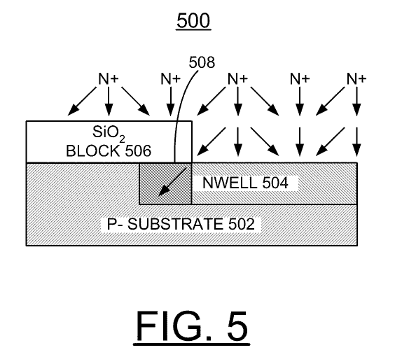

To illustrate the design method, refer now to FIGS. 3 and 4. FIG. 3 shows a CMOS circuit 300 containing a PFET 302 and NFET 304 connected between a voltage supply VDD and ground. The schematic properties for each NFET 304 and PFET 302 contain a variable (Xn for NFETs, Xp for PFETs) representing the distance between the specified transistor and its adjacent NWELL or PWELL. This variable, Xn or Xp, is also found in the transistor simulation models and is part of the equation for the transistor's threshold voltage (Vt).

In FIG. 4, there are shown exemplary steps for implementing CMOS circuits having variable threshold voltage transistors in accordance with the preferred embodiment. In the design of a CMOS circuit, a CMOS transistor is identified that requires a changed threshold voltage as indicated at a block 402.

For an N-channel field effect transistor (NFET) such as NFET 304 in FIG. 3, the distance is adjusted between an NWELL edge or a PWELL edge and the adjacent N-channel field effect transistor (NFET) 304 so that the threshold voltage for the NFET transistor 304 is changed to provide the required threshold voltage as indicated at a block 404.

For a P-channel field effect transistor (PFET) such as PFET 302 in FIG. 3, the distance is adjusted between the PWELL edge and an adjacent P-channel field effect transistor (PFET) 302 so that the threshold voltage for the PFET transistor 302 is changed to provide the required threshold voltage as indicated at a block 406.

The variable threshold voltage transistor design program 134 includes corresponding transistor simulation models to reflect these characteristics and change the Vt accordingly. The variable threshold voltage transistor design program 134 includes modifications of conventional DRC rules and/or LVS checks, which would prevent placing an adjacent shape of PWELLs and NWELLs too close to a PFET and NFET.

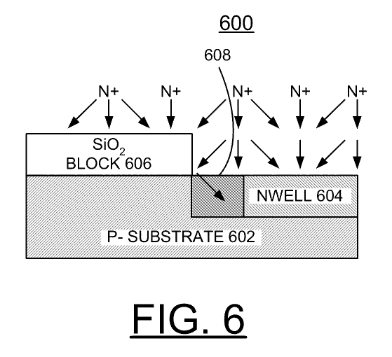

Referring now to FIGS. 5 and 6, there are shown a respective implantation process for NWELLs in accordance with the preferred embodiment. CMOS silicon technologies exhibit a characteristic called well proximity effects. This phenomena occurs during the doping process to create NWELL and PWELL regions.

In FIG. 5, a CMOS structure 500 is shown including a P-substrate 502, an NWELL 504, a SIO₂ block 506 or photoresist, and an outside WELL region 508 having implanted N-type ions.

In FIG. 6, a CMOS structure 600 is shown including a P-substrate 602, an NWELL 604, a SIO₂ block 606 or photoresist, and an inside WELL region 608 having implanted N-type ions.

Photoresist 506, 606 is placed over the entire silicon surface 502, 602 except where NWELLs 504 and PWELLs are to be created. During the NWELL creation process N-type ions are not only implanted in the desired region, but some of the N-type ions are implanted into NFET regions near the NWELL edge 608, as shown in FIG. 6 or “back scatter” into PFET regions. The N-type ions are not always implanted perpendicular to the silicon surface. Some ions are implanted at an angle such that they can penetrate NFET regions 508 under the photoresist 506, as shown in FIG. 5. During the PWELL creation process P-type ions are not only deposited in the desired region, but some of the P-type ions are implanted into PFET regions near the PWELL edge or “back scatter” into NFET regions. Some p-type ions are implanted at an angle such that they can penetrate PFET regions under the photoresist.

PWELLs and NWELLs respectively are created by high energy P-type and N-type implants. Scattering of the P-type and N-type ions back into the PWELLs and NWELLs increases the hole or electron concentration in the PWELLs and NWELLs. The threshold voltage of a FET transistor can be described by the following equation:

Vt=Vt0+g((2f_{f}+V_{SB})^{0.5}−(2f_{f})^{0.5})

g=(1/Cox)(2qeN_{A})^{0.5}

where Vt represents the transistor threshold voltage and N_{A} represents the carrier concentration of the well.

The above equation shows that increasing the carrier concentration of the well (N_{A}) increases the threshold voltage. Conversely, decreasing the carrier concentration of the well decreases the threshold voltage. The well proximity effect advantageously is used to provide a field effect transistor with an adjustable Vt without adding any mask levels.

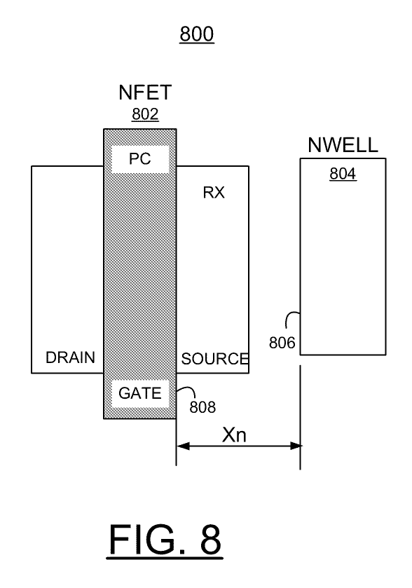

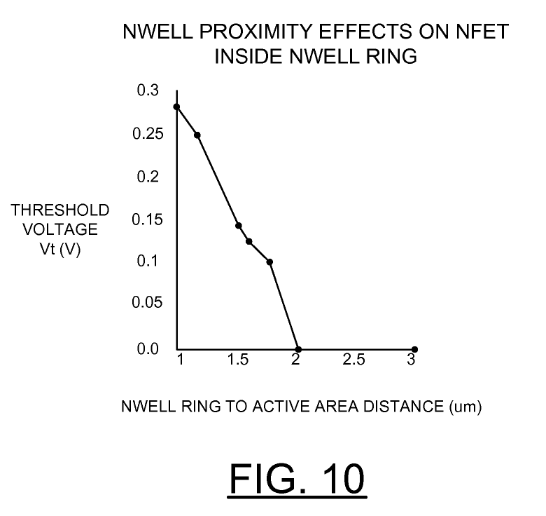

FIG. 8 illustrates an example CMOS circuit 800 having a variable threshold voltage NFET 802 selectively spaced from an NWELL 804 in accordance with the preferred embodiment. By placing an NWELL 804 adjacent to NFETs as shown in FIG. 8, the Vt of the NFET advantageously is tuned by adjusting the distance (Xn) between the NWELL region's inner edge 806 and the active area 808 of the NFET 802, defined by the intersection of polysilicon PC with the recessed oxide RX. The resulting NFET transistor has a threshold voltage Vt vs. Xn similar to that shown in FIG. 10.

Similarly by placing a PWELL region adjacent to PFETs (not shown), the Vt of the PFET advantageously is tuned by adjusting the distance (Xp) between the PWELL region's inner edge and the active area of the PFET. The resulting PFET has a threshold voltage Vt related to the distance Xp.

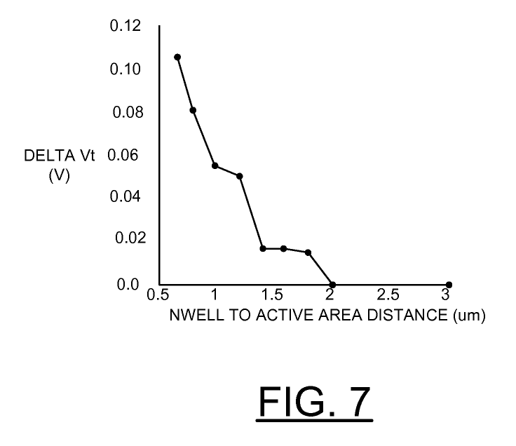

Referring now to FIG. 7, there is shown a chart illustrating example NWELL proximity effects on an NFET in accordance with the preferred embodiment. In FIG. 7, the change in threshold voltage Vt is shown. The delta Vt is plotted along the vertical axis in volts with respect to an NWELL to active area distance in micrometers along the horizontal axis.

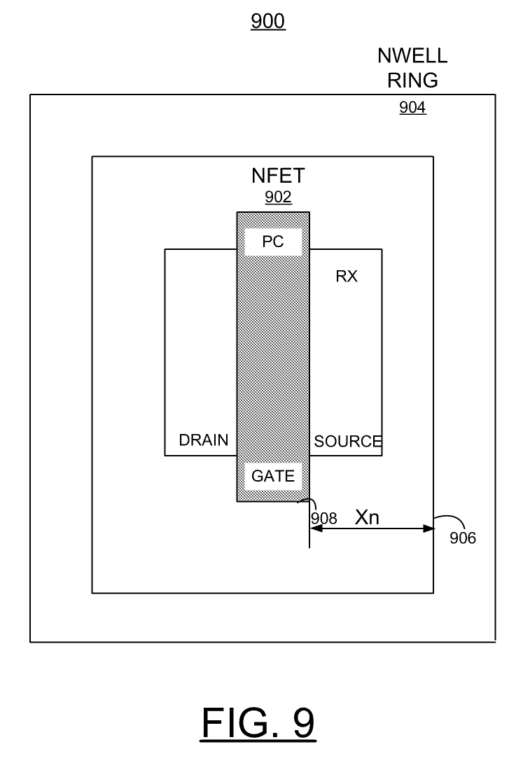

In accordance with features of the invention, it should be understood that the adjacent NWELL or PWELL edge could include an inner edge of an NWELL or PWELL segment as shown in FIG. 8. Also, it should be understood that the adjacent NWELL or PWELL edge could include an inner edge of an NWELL Ring or PWELL Ring around the entire NFET or PFET, for example, as illustrated in the example CMOS circuit 900 of FIG. 9. This ring configuration results in an even greater threshold adjustment capability than shown in FIGS. 7 and 8.

FIG. 9 illustrates an example CMOS circuit 900 having a variable threshold voltage NFET 902 selectively spaced from an NWELL Ring 904 in accordance with the preferred embodiment. By placing an NWELL Ring 904 adjacent to NFETs as shown in FIG. 9, the Vt of the NFET advantageously is tuned by adjusting the distance (Xn) between the NWELL Ring's inner edge 906 and the active area 908 of the NFET 902, defined by the intersection of polysilicon PC with the recessed oxide RX.

Referring now to FIG. 10, there is shown a chart illustrating example NWELL proximity effects on an NFET inside an NWELL Ring in accordance with the preferred embodiment. In FIG. 10, the change in threshold voltage Vt is shown for the NWELL ring embodiment of the invention. The delta Vt is plotted along the vertical axis in volts with respect to an NWELL Ring to active area distance in micrometers along the horizontal axis.

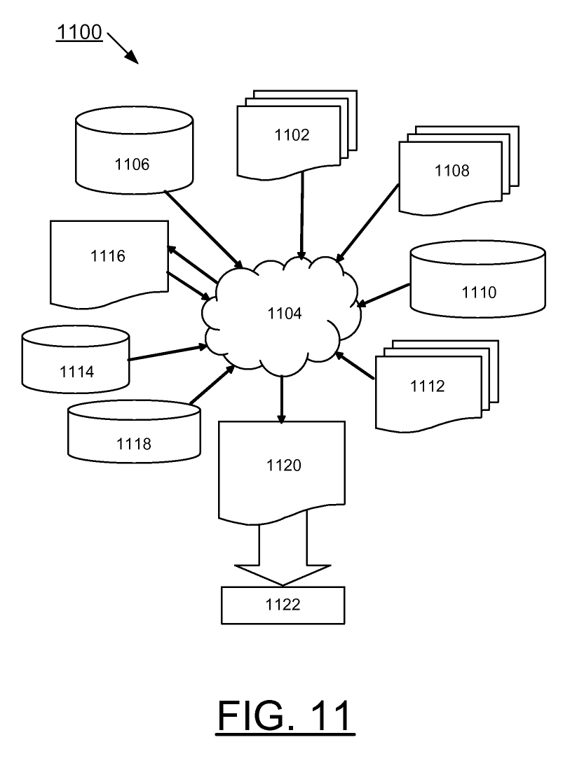

FIG. 11 shows a block diagram of an example design flow 1100. Design flow 1100 may vary depending on the type of IC being designed. For example, a design flow 1100 for building an application specific IC (ASIC) may differ from a design flow 1100 for designing a standard component. Design structure 1102 is preferably an input to a design process 1104 and may come from an IP provider, a core developer, or other design company or may be generated by the operator of the design flow, or from other sources. Design structure 1102 comprises circuit 200 in the form of schematics or HDL, a hardware-description language, for example, Verilog, VHDL, C, and the like. Design structure 1102 may be contained on one or more machine readable medium. For example, design structure 1102 may be a text file or a graphical representation of circuits 300, 700, 800. Design process 1104 preferably synthesizes, or translates, circuits 300, 700, 800 into a netlist 1106, where netlist 1106 is, for example, a list of wires, transistors, logic gates, control circuits, I/O, models, etc. that describes the connections to other elements and circuits in an integrated circuit design and recorded on at least one of machine readable medium. This may be an iterative process in which netlist 1106 is resynthesized one or more times depending on design specifications and parameters for the circuits.

Design process 1104 may include using a variety of inputs; for example, inputs from library elements 1108 which may house a set of commonly used elements, circuits, and devices, including models, layouts, and symbolic representations, for a given manufacturing technology, such as different technology nodes, 32 nm, 45 nm, 90 nm, and the like, design specifications 1110, characterization data 1112, verification data 1114, design rules 1116, and test data files 11111, which may include test patterns and other testing information. Design process 1104 may further include, for example, standard circuit design processes such as timing analysis, verification, design rule checking, place and route operations, and the like. One of ordinary skill in the art of integrated circuit design can appreciate the extent of possible electronic design automation tools and applications used in design process 1104 without deviating from the scope and spirit of the invention. The design structure of the invention is not limited to any specific design flow.

Design process 1104 preferably translates an embodiment of the invention as shown in FIGS. 3, 7, and 8 along with any additional integrated circuit design or data (if applicable), into a second design structure 1120. Design structure 1120 resides on a storage medium in a data format used for the exchange of layout data of integrated circuits, for example, information stored in a GDSII (GDS2), GL1, OASIS, or any other suitable format for storing such design structures. Design structure 1120 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 3, 7, and 8. Design structure 1120 may then proceed to a stage 1122 where, for example, design structure 1120 proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

What is claimed is:

1. A variable threshold voltage transistor circuit in a complementary metal oxide semiconductor (CMOS) semiconductor chip comprising:
a plurality of variable threshold voltage transistors,
said variable threshold voltage transistors selectively utilizing the NWELL and PWELL proximity effects of the CMOS semiconductor chip;
each of said variable threshold voltage transistors having a selectively adjusted distance between an adjacent field effect transistor (FET) and an edge of the NWELL and PWELL for selectively providing a threshold voltage for the adjacent FET.

2. The variable threshold voltage transistor circuit as recited in claim 1, wherein said adjacent FET includes an adjacent N-channel field effect transistor (NFET) and said selectively adjusted distance includes a selectively adjusted distance between said adjacent NFET and an NWELL edge, the threshold voltage for the NFET transistor is changed.

3. The variable threshold voltage transistor circuit as recited in claim 1, wherein said adjacent FET includes an adjacent N-channel field effect transistor (NFET) and said selectively adjusted distance includes a selectively adjusted distance between said adjacent NFET and a PWELL edge, the threshold voltage for the NFET transistor is changed.

4. The variable threshold voltage transistor circuit as recited in claim 1, wherein said adjacent FET includes an adjacent P-channel field effect transistor (PFET) and said selectively adjusted distance includes a selectively adjusted distance between said adjacent PFET and a PWELL edge, the threshold voltage for the PFET transistor is changed.

5. The variable threshold voltage transistor circuit as recited in claim 1, wherein said adjacent FET includes an adjacent P-channel field effect transistor (PFET) and said selectively adjusted distance includes a selectively adjusted distance between said adjacent PFET and an NWELL edge, the threshold voltage for the PFET transistor is changed.

6. The variable threshold voltage transistor circuit as recited in claim 1, wherein said edge includes an inner edge of an NWELL Ring around an entire N-channel field effect transistor (NFET), or around an entire P-channel field effect transistor (PFET).

7. The variable threshold voltage transistor circuit as recited in claim 1, wherein said edge includes an inner edge of a PWELL Ring around an entire P-channel field effect transistor (PFET), or around an entire N-channel field effect transistor (NFET).

8. A method for implementing variable threshold voltage transistors in a complementary metal oxide semiconductor (CMOS) semiconductor chip comprising:
forming a plurality of variable threshold voltage transistors selectively utilizing the NWELL and PWELL proximity effects of the CMOS semiconductor chip; and
selectively adjusting a distance between an adjacent field effect transistor (FET) and an edge of the NWELL and PWELL for selectively providing a threshold voltage for the adjacent FET.

9. The method as recited in claim 8 wherein forming said plurality of variable threshold voltage transistors includes forming an adjacent N-channel field effect transistor (NFET) and selectively adjusting a distance between said NFET and an NWELL edge, the threshold voltage for the NFET transistor is changed.

10. The method as recited in claim 8 wherein forming said plurality of variable threshold voltage transistors includes forming an adjacent N-channel field effect transistor (NFET) and selectively adjusting a distance between said NFET and a PWELL edge, the threshold voltage for the NFET transistor is changed.

11. The method as recited in claim 8 wherein forming said plurality of variable threshold voltage transistors includes forming an adjacent P-channel field effect transistor (PFET) and selectively adjusting a distance between said PFET and a PWELL edge, the threshold voltage for the PFET transistor is changed.

12. The method as recited in claim 8 wherein forming said plurality of variable threshold voltage transistors includes forming said plurality of variable threshold voltage transistors includes forming an adjacent P-channel field effect transistor (PFET) and selectively adjusting a distance between said PFET and an NWELL edge, the threshold voltage for the PFET transistor is changed.

13. The method as recited in claim 8 wherein selectively adjusting a distance between an adjacent field effect transistor (FET) and an edge of the NWELL and PWELL for selectively providing a threshold voltage for the adjacent FET includes selectively adjusting a distance between said FET and an inner edge of an NWELL Ring around an entire N-channel field effect transistor (NFET), or selectively adjusting a distance between said FET and an inner edge of an NWELL Ring around an entire P-channel field effect transistor (PFET).

14. The method as recited in claim 8 wherein selectively adjusting a distance between an adjacent field effect transistor (FET) and an edge of the NWELL and PWELL for selectively providing a threshold voltage for the adjacent FET includes selectively adjusting a distance between said FET and an inner edge of an PWELL Ring around an entire P-channel field effect transistor (PFET), or selectively adjusting a distance between said FET and an inner edge of an PWELL Ring around an entire N-channel field effect transistor (NFET).

15. A design structure embodied in a machine readable medium used in a design process, the design structure comprising:
a variable threshold voltage transistor circuit tangibly embodied in the machine readable medium used in the design process, said variable threshold voltage transistor circuit for implementing variable threshold voltage transistors in a semiconductor chip, said variable threshold voltage transistor circuit including
a plurality of variable threshold voltage transistors,
said variable threshold voltage transistors selectively utilizing the NWELL and PWELL proximity effects of the CMOS semiconductor chip;
each of said variable threshold voltage transistors having a selectively adjusted distance between an adjacent field effect transistor (FET) and an edge of the NWELL and PWELL for selectively providing a threshold voltage for the adjacent FET; wherein the design structure, when read and used in the manufacture of a semiconductor chip produces a chip comprising said variable threshold voltage transistor circuit.

16. The design structure of claim 15, wherein the design structure comprises a netlist, which describes said variable threshold voltage transistor circuit.

17. The design structure of claim 15, wherein the design structure resides on storage medium as a data format used for the exchange of layout data of integrated circuits.

18. The design structure of claim 15, wherein the design structure includes at least one of test data files, characterization data, verification data, or design specifications.

19. The design structure of claim 15, wherein said edge of the NWELL and PWELL includes an inner edge of an NWELL Ring around an entire N-channel field effect transistor (NFET), or an inner edge of an NWELL Ring around an entire P-channel field effect transistor (PFET)

20. The design structure of claim 15, wherein said edge of the NWELL and PWELL includes an inner edge of a PWELL Ring around an entire P-channel field effect transistor (PFET), or an inner edge of an PWELL Ring around an entire N-channel field effect transistor (NFET).
